(19) United States
(12) Patent Application Publication
(10) Pub. No.: US 2004/0012100 A1
(43) Pub. Date: Jan. 22, 2004

(54) Photosensitive imaging device having photosites isolated with deep trenches

(75) Inventor: Paul A. Hosier, Rochester, NY (US)

Correspondence Address: Patent Documentation Center, Xerox Corporation, Xerox Square 20th Floor, 100 Clinton Ave. S., Rochester, NY, 14644, US

(73) Assignee: Xerox Corporation

(21) Appl. No.: 10/199,840

(22) Filed: Jul. 18, 2002

(51) Int. Cl. H01L 27/00

(52) U.S. Cl. 257/929

(57) ABSTRACT

In a photosensitive imaging chip, such as employing CCD or CMOS technology, each photosite is electrically isolated from other structures on the chip by a trench. The trench extends through an epitaxial layer of the chip and intersects a heavily-doped substrate layer of the chip by at least 1 μm. The trench can be formed by plasma etching, and filled with polysilicon.

### TECHNICAL FIELD

The present invention relates to photosensitive imaging devices using CCD or CMOS technology, as would be found, for example, in digital cameras and document scanners used in office equipment.

### BACKGROUND

Image sensor arrays, such as found in digital document scanners and digital cameras, typically comprise a linear array of photosites which raster scan a focused image, or an image bearing document, and convert the set of microscopic image areas viewed by each photosite to image signal charges. Following an integration period the image signal charges are amplified and transferred to a common output line or bus through successively actuated multiplexing transistors. (As used herein, the word “photosite” shall apply to the structure defining a surface on which light is to impinge and thereby create a measurable signal, regardless of the specific technology involved for accumulating light-related charges or generating signals.)

Currently there are two common basic technologies for creating such arrays of photosites: charge-coupled devices, or CCD's, and CMOS. In CMOS, the photosites include photodiodes where impinging light creates electron-hole pairs, resulting in a measurable charge. In the scanning process, bias and reset charges are applied in a predetermined time sequence during each scan cycle to read out the charge from each photosite, yielding image data which can be subsequently digitized.

The concept of “isolation” is fairly common in the art of CMOS circuitry. Basically the idea is to create structures which isolate different circuit elements within a single chip, so the activities of one circuit on the chip do not interfere with those of another. With photosensitive chips, however, an additional design problem occurs because of the inherent photosensitivity of specific areas of the chip. Areas of the chip intended to act as photosites of course generate electronhole pairs whenever they are exposed to light, but other areas within the chip exhibit photosensitive properties as well and will generate electron-hole pairs even in portions of the chip which are not intended to act as photosites. It is therefore desirable to provide a structure wherein each photosite is electrically isolated from other structures, particularly neighboring photosites, so that accurate signals representing the light impinging on one photosite is allowed to contribute to the output signal only for that photosite.

### DESCRIPTION OF THE PRIOR ART

U.S. Pat. Nos 4,737,854; 5,081,536 and 5,105,277 give examples of a basic CMOS-based imaging device.

U.S. Pat. No. 5,804,465 discloses an isolation and anti-blooming structure for use in a CCD-based imaging apparatus.

U.S. Pat. No. 5,930,595 discloses isolation principles as would be used in the context of micromachined mechanical sensors and actuators.

U.S. Pat. No. 5,936,261 discloses a use of an isolation principle in a photosensitive apparatus. Oxide isolation is provided between elevated PIN diodes, but the isolation stops on a horizontal oxide surface.

U.S. Pat. No. 6,066,883 discloses an image sensor array in which each photosite includes a guardring, in the form of a biased diffusion area, which prevents leakage of charge relative to the photosite.

U.S. Pat. No. 6,140,156 discloses a fabrication method for a photodiode having an isolation structure. A trench is provided to reduce sidewall capacitance of a photodiode, but it does not intersect a heavily doped region of an epitaxial wafer.

### SUMMARY OF THE INVENTION

According to one aspect of the present invention, there is provided a chip forming a photosensitive apparatus, comprising a heavily doped substrate region, and a lightly doped epitaxial region disposed on the substrate region, the epitaxial region defining a main surface of the chip. A trench extends from the main surface of the chip to the substrate region, and intersects with the substrate region. The trench defines a boundary between a first photosite and a second photosite.

### BRIEF DESCRIPTION OF THE DRAWINGS

FIG. 1 is a plan view of a single photosensitive chip of a general design found, for example, in a full-color document scanner.

FIG. 2 is a sectional elevational view, through a line such as 2-2 in FIG. 1, showing the structure of two neighboring photosites.

### DETAILED DESCRIPTION

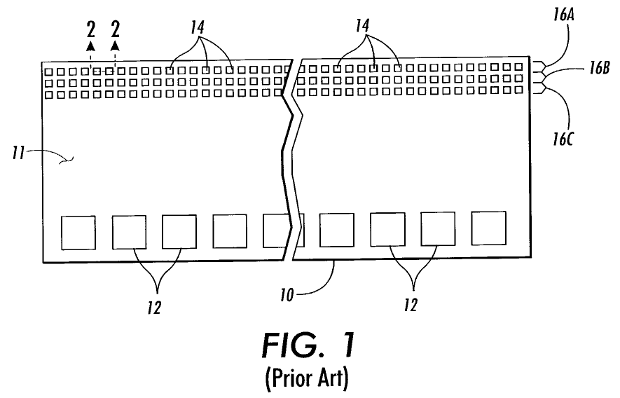

FIG. 1 is a plan view of a single photosensitive chip, generally indicated as 10, of a general design found, for example, in a full-color document scanner. A typical design of a full-page-width scanner will include a plurality of chips 10, each chip being approximately one-half to one inch in length, the chips being butted end-to-end to form an effective collinear array of photosites, which extends across a page image being scanned. (In a digital camera context, the various photosites, on one or more chips, would typically be organized in a two-dimensional array.) Each chip 10 is a silicon-based integrated circuit chip having defined in a main surface thereof, in addition to any number of contact pads such as 12, three independently-functioning linear arrays of photosites, each photosite being here indicated as 14. In a hard-copy scanner such as found in office equipment, the photosites are disposed in three parallel rows which extend across a main dimension of the chip 10, these individual rows being shown as 16a, 16b, and 16c. Each individual row of photosites on chip 10 can be made sensitive to a particular color, by applying to the particular row 16a, 16b, 16c a spectrally translucent filter layer (not shown) which covers only the photosites in a particular row. Generally, each individual photosite 14 is adapted to output a charge or voltage signal indicative to the intensity of light of a certain type impinging thereon; various structures indicated generally as 11 and disposed within the chip, such as transfer circuits, or charge-coupled devices, are known in the art for processing signal outputs by the various photosites 14.

Each photosite 14 is of a generally rectangular shape, defining a perimeter, the perimeter of each photosite being spaced from the perimeter of a neighboring photosite by a spacing distance. According to one preferred design of a three-row, full-color photosensitive chip, for an image resolution of 400 spots per linear inch, each photosite 14 has a dimension in the plan-view direction of 47.5 micrometers along the direction of extension of the linear arrays, and 63.5 micrometers along the direction perpendicular to the direction of the linear array. Further, a desirable spacing between the borders of adjacent photosites 14 is approximately seven micrometers from one border of a photosite 14 in row 16a to the border of a neighboring photosite in row 16b. Along the length of the linear array, the spacing between borders of adjacent photosites within a particular row 16 is approximately fourteen to sixteen micrometers, as some designs of photosensitive chips will have various distances between different pairs of adjacent photosites for optical purposes.

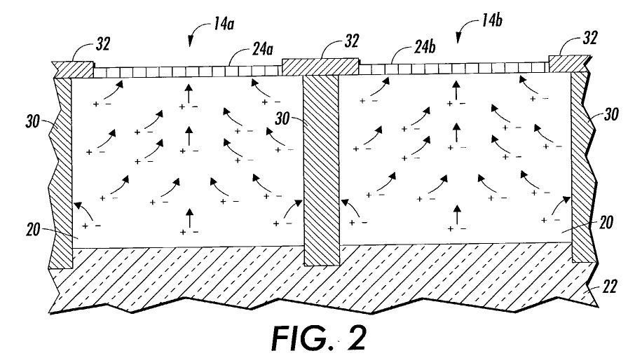

FIG. 2 is a sectional view, through a line such as 2-2 in FIG. 1, showing the structure of two neighboring photosites, marked 14a and 14b, according to an embodiment of the present invention. Although the two neighboring photosites are adjacent along a linear array in FIG. 1, the invention can be practiced with any border area between any pair of photosites, such as in a two-dimensional array of photosites, and be associated with any or all borders or portions thereof defining a photosite.

In the illustrated embodiment, the chip 10 comprises, among other structures, an epitaxial layer 20 disposed on a substrate layer 22. The top of epitaxial layer 20, as shown in the Figure, forms a main surface of the chip 10. In a practical embodiment, the epitaxial layer 20 is in the form of a P− doped silicon layer, and the substrate layer 22 is in the form of a P+ silicon doped layer. More broadly, the epitaxial layer 20 is lightly doped, and the substrate layer 22 is heavily doped. Disposed on the epitaxial layer for each photosite 14a, 14b is a diffusion 24a and 24b. The diffusions can be solid planar rectangular diffusions or implants, or they can be formed in annular shapes as viewed from above. (Oxide layers 32 between each photosite will be discussed below.)

The diffusion 24a, 24b, in combination with the epitaxial layer 20 and substrate layer 22, causes each photosite 14a, 14b to form a photodiode. When 10 light impinges on the main surface of the chip, electron-hole pairs are generated in the epitaxial layer 20 and collected as charges within each photodiode corresponding to each photosite 14a, 14b, as shown by the symbols and arrows within the epitaxial layer 20. These charges can be used as image-based signals, whether the chip 10 functions as a CMOS, CCD, or other type of photosensitive device.

As mentioned above, in a practical imaging apparatus, it is important to electrically isolate each photosite from its neighbors, and from any other areas on the surface of the chip. In an imaging sense, charges created by light impinging on a particular photosite such as 14a should stay within the photodiode of the photosite, so that the charge output is an accurate result of the intensity of light on photosite 14a at a given time. What must be avoided is charge created by light falling on photosite 14b being collected at photosite 14a, or vice-versa: such mixing will adversely affect the spatial resolution of the device. Further, each photosite must be electrically isolated from other portions of the chip which may generate charges yet are not intended to function as photosites in any way.

Since the minority carriers (in the present embodiment, electrons, in p-type silicon) of a light-generated electron-hole pair move by diffusion, it is equally likely that a single carrier will randomly walk in any direction. Given equilibrium conditions for a set of minority carriers, the carriers will diffuse according to the diffusion law, given the boundary conditions for carrier densities at certain boundaries. Since the depletion field of the photodiode quickly sweeps minority carriers at the edge of the depletion layer across the junction, the minority carrier concentration at the junction depletion layer edge (i.e., between layers 20 and 24) is near zero. This boundary condition can be used to determine the amount of charge that is collected at each photodiode.

In FIG. 2 there can be seen, disposed between photosites 14a and 14b, a trench 30. Trench 30 is in the form of a void in the silicon of chip 10 between the photosites such as 14a and 14b, and extends from the top surface of the chip 10, through epitaxial layer 20, to a point intersecting the substrate layer 22. The trench 30, in various embodiments, can be filled with different materials, as will be described below. At the top surface of the trench structure 30 can be placed a field oxide layer 32, although the field oxide layer 32 is not necessary for the invention as long as the photodiode implants are isolated at the surface of epitaxial layer 20.

The trench 30 can be made in various ways that are known in the art of semiconductor processing, usually with some type of plasma etch. The trench 30 includes an insulating layer on its sidewalls, the most common type comprising silicon oxide (SiO₂). The trench 30 can be filled with oxide, polyimide, or more preferably polysilicon due to stress concerns. Since minority carrier recombination may occur on the trench Si—SiO₂ interface, it may be desirable to implant or diffuse some boron into the trench before the oxide sidewalls are grown. The boron doping should be larger than the doping in the epitaxial layer 20 so that the built-in field gradient will push minority carriers away from the trench sidewalls.

The trench 30 needs to be deep enough to at least intercept the substrate layer 22 at some point, preferably about 1.0 μm into the upward slope between the epitaxial layer 22 (about 10¹⁵ atoms/cm⁻³)and the heavily doped substrate layer 20 (above 10¹⁸ atoms/cm⁻³). The built-in electrical field within each photosite will keep most minority carriers generated above that field out of the substrate layer 22. Therefore, the trench 30 should at least be deep enough to intersect the sharp rise in P+ doping in substrate layer 22. If the P+ doping in the substrate layer 22 is at least doubling every 1 μm, the minority carrier drift current due to the built-in electrical field will overpower any diffusion. This occurs quite early (that is, as depth increases) in the P+ doping intersection.

There are two factors to consider for the depth needed to prevent mixing of carriers (that is, charges) generated in the P+ substrate region 22. First, the spectrum of impinging light will determine how many electron-hole pairs are generated deep in the silicon forming chip 10. For example, about 28% of red (650 nm) light penetrates deeper than 4 μm (15% deeper than 6 μm), but only 3% of green (550 nm) light goes deeper than 4 μm. Given the spectrum, and geometry of the photosite, a depth of trench 30 could be determined to allow a certain amount of mixing. The final factor is the band to band auger minority carrier recombination that occurs in highly doped regions. This recombination limits the diffusion length to a few microns (on the order of 5 μm). Therefore, there is no need to go more than a few μms into the heavily doped region to essentially guarantee that minority carriers do not make it to the next pixel because of either geometry, electric field or recombination considerations. For practical purposes, red mixing is not as much of a concern for most visible light applications because of the eyes' sensitivity to spatial color variation. Therefore, for most applications, an intersection of the trench into about 1 μm of the P+ doping slope associated with substrate layer 22 should be adequate to eliminate essentially all mixing that will affect image quality.

1. A chip forming a photosensitive apparatus, comprising:
a heavily doped substrate region;
a lightly doped epitaxial region disposed on the substrate region, the epitaxial region defining a main surface of the chip; and
a trench extending from the main surface of the chip to the substrate region, the trench intersecting with the substrate region, the trench defining a boundary between a first photosite and a second photosite.

2. The chip of claim 1, the trench intersecting the substrate region by at least 1 μm.

3. The chip of claim 1, the trench intersecting the substrate region by at least 5 μm.

4. The chip of claim 1, the trench intersecting the substrate region to a point where the doping of the substrate layer doubles with every 1 μm of depth.

5. The chip of claim 1, the trench intersecting the substrate region to a doping of at least 10¹⁷ atoms/cm⁻³.

6. The chip of claim 1, wherein the substrate is P+ and the epitaxial layer is P−.

7. The chip of claim 6, further comprising an N+ diode layer disposed on the main surface.

8. The chip of claim 1, further comprising oxide disposed in the trench.

9. The chip of claim 1, further comprising polyimide disposed in the trench.

10. The chip of claim 1, further comprising polysilicon disposed in the trench.

11. The chip of claim 1, further comprising an insulating sidewall disposed in the trench, the sidewall comprising silicon oxide.

12. The chip of claim 1, further comprising boron doping associated with the trench.
